(19) United States
(12) Patent Application Publication
(10) Pub. No.: US 2014/0027171 A1
(43) Pub. Date: Jan. 30, 2014

(54) PLATE FOR A SHIELD CAN FOR AN SMD PROCESS, MANUFACTURING METHOD THEREOF, AND SHIELD CAN USING THE PLATE

(71) Applicants: Min Hwa Song, Incheon (KR); Eun Gyo Oh, Pyeongtaek-si (KR)

(72) Inventors: Min Hwa Song, Incheon (KR); Eun Gyo Oh, Pyeongtaek-si (KR)

(21) Appl. No.: 14/111,110

(22) PCT Filed: Oct. 6, 2011
(86) PCT No.: PCT/KR2011/007388

§ 371 Date: Oct. 15, 2013

(30) Foreign Application Priority Data
Apr. 13, 2011 (KR) 10-2011-0034180

(51) Int. Cl. H05K 9/00; H05K 13/00

(52) U.S. Cl. CPC H05K 9/0049; H05K 13/00
USPC 174/377; 428/447; 156/60

(57) ABSTRACT

The shield can plate for a SMD process in accordance with the present invention, includes: a metal conductive layer which is made of one selected from a group consisting of copper (Cu), zinc (Zn), nickel (Ni), silver (Ag), iron (Fe) and chromium (Cr) or an alloy thereof, or clad metal, performs an electromagnetic shielding function and maintains a physical structure when a shield can is constructed; an insulating layer which is made of one or more of polyethylene terephthalate (PET) and polyethylene naphthalate (PEN), which are crystalline polymers, wherein the insulating layer is laminated on one side of the metal conductive layer; and a silane-based coupling layer interposed between the metal conductive layer and the insulating layer.

### CROSS-REFERENCE TO RELATED APPLICATION

This application claims the benefit of Korean Application No. 10-2011-0034180, filed on Apr. 13, 2011, with the Korean Intellectual Property Office, the disclosure of which is incorporated herein by reference.

### BACKGROUND OF THE INVENTION

1. Field of the Invention

The present invention relates to a shield can, and more particularly, to a shield can plate with high heat resistance and insulating property, which serves as a shield can basic material for shielding electronic components from an electromagnetic wave, a method of manufacturing the shield can plate, and a shield can which is manufactured with the shield can plate and covers the electronic components on a printed circuit board (PCB).

2. Description of the Related Art

Recent rapid advancement in electronics accounts for an increasing share of electronic components throughout the whole industrial fields including development of various electronic communication devices including mobile terminals and so on, compactness and lightness of electronic products, and electronization of non-electronic parts such as machinery, devices, apparatuses and so on. To this end, high integration and high performance of electronic components are more and more being accelerated.

In this connection, an electromagnetic wave having a direct effect on performance of electronic components is in much concern. An electromagnetic wave refers generally to a physical phenomenon that an electromagnetic field with periodically-varying intensity propagates in the space. However, recently, in most cases, an electromagnetic wave means an electromagnetic noise which is emitted from electronic components or may have an effect on the electronic components. As measures against this electromagnetic noise, two aspects, two aspects of a noise emission measure (against EMI) and an immunity measure (against EMS) are being carefully discussed.

It is known that an electromagnetic wave is a resultant wave of an electric field and a magnetic field in which the magnetic field is proportional to a voltage but is inversely proportional to a distance from an obstacle, whereas the electric field has little effect on an obstacle while being proportional to current but being inversely proportional to the distance. Many users pay attention on electromagnetic wave shielding measures to meet both of the noise emission measure and the immunity measure. At present, practical ways for materials, structures and methods for electromagnetic wave shielding are being studied.

Table 1 shows kinds, shielding effects and required costs of electromagnetic wave shielding materials currently used at present.

TABLE 1

| | | |
|---|---|---|
| | Shielding | |
| Shielding method | effect | Costs |

| | | | |
|---|---|---|---|
| Metal plate | Sheeting | 5 | 103 |
| | Metal + plastic | 5 | 100 |
| Conductive | Metal spraying (Zn) | 3 | 115 |
| surface | Conductive painting | 3 | 121 |
| treatment of | (Cu and Ni) | | |
| plastic | Vacuum deposition (AI) | 4 | 135 |
| | Electroless plating | 3 | 157 |
| | (Cu and Ni) | | |
| Conductive | Injection molding of | 4 | 110 |
| plastic | conductive plastic | | |
| | Dual injection molding | 4 | 131 |

On the one hand, recently, an electromagnetic wave shielding component called a shield can is being used for electromagnetic wave shielding of electronic components mounted on a PCB.

In general, a shield can shows a cover shape coupled to a PCB to cover electronic components mounted on a PCB and is completed by attaching an insulating tape for insulation from electronic components along an inner side of a housing obtained by metal or ally sheeting.

Depending on a fixed type, a typical shield can may be classified into a clip type using a clip preformed on a PCB and a SMD (Surface Mount Device) type directly soldered to a PCB. The clip type shield can has a disadvantage of complicated process and high costs due to formation of separate clips on a PCB although it requires no material property except conductivity of a housing and insulation of an insulating tape. On the other hand, the SMD type shield can has an advantage of simple process and low costs as it can be directly soldered to a PCB although it requires heat-resistance against a high temperature of 250° C. for soldering in addition to conductivity and insulation.

However, both of the clip type and SMD type shield can require an insulating tape for insulation from electronic components. In particular, they require a plurality of insulating tapes if a step or a multi-layered structure exists in the interior of the shield can. Accordingly, a process for this requires additional processes, high costs and much time as it relies entirely on a manual work. In addition, for the SMD type shield can, an insulating property may be frequently lost as an adhesive material of an insulating tape is melted due to high temperature soldering to contaminate electronic components or separate the insulating tape.

It is an actual circumference that the clip type shield can is being used irrespective of disadvantage of complicated process and high costs.

### SUMMARY OF THE INVENTION

Accordingly, it is an object of the present invention to provide a shield can with excellent electromagnetic wave shielding and insulation as well as high heat-resistance.

In more detail, it is an object of the present invention to provide a shield can plate with excellent electromagnetic wave shielding and excellent insulation from electronic components and high heat-resistance against high temperature soldering without any separate insulating tape, a method of manufacturing the same, and a shield can using the same.

To achieve the above objects, according to an aspect of the invention, there is provided a shield can plate for a SMD process, including: a metal conductive layer which is made of one selected from a group consisting of copper (Cu), zinc (Zn), nickel (Ni), silver (Ag), iron (Fe) and chromium (Cr) or an alloy thereof, or clad metal, performs an electromagnetic shielding function and maintains a physical structure when a shield can is constructed; an insulating layer which is made of one or more of polyethylene terephthalate (PET) and polyethylene naphthalate (PEN), which are crystalline polymers, wherein the insulating layer is laminated on one side of the metal conductive layer; and a silane-based coupling layer interposed between the metal conductive layer and the insulating layer.

Preferably, the metal conductive layer is made of one selected from a group consisting of german silver, phosphor bronze, brass, stainless and beryllium copper, or clad metal selected from a group consisting of phosphor bronze/stainless steel/phosphor bronze and german silver/stainless steel/german silver, and the insulating layer is made of one of PET and PEN, which are crystalline polymers, and has a thickness of 1 to 70 μm.

According to another aspect of the invention, there is provided a method of manufacturing a shield can plate for a SMD process, including: preparing a metal sheet which is made of one selected from a group consisting of copper (Cu), zinc (Zn), nickel (Ni), silver (Ag), iron (Fe) and chromium (Cr) or an alloy thereof, or clad metal, performs an electromagnetic shielding function and maintains a physical structure when a shield can is constructed; preparing a synthetic resin sheet in the form of a roll, the synthetic resin sheet being made of one or more of thermoplastic polyester resins including polyethylene terephthalate (PET) and polyethylene naphthalate (PEN), or a mixture thereof; and drying the metal sheet and the synthetic resin sheet after passing between a pair of compressive rollers with a temperature of 220 to 280° C. and a pressure of 5 to 30 Kgf/cm², at a speed of 1 to 10 mm/min, with the metal sheet and the synthetic resin sheet overlapped.

Before overlapping the metal sheet and the synthetic resin sheet, the method may further includes interposing a silane-based coupling layer, as a primer for adhesion, between the metal sheet and the synthetic resin sheet.

According to another aspect of the invention, there is provided a shield can which is formed by the above-described shield can plate for a SMD process and covers electronic components mounted on a PCB, wherein the shield can is soldered to the PCB and has a cover shape covering the electronic components such that the metal conducive layer is exposed to the external and the insulating layer directs to the electronic components.

The shield can plate of the present invention has advantages of effective shielding of an electromagnetic wave due to excellent conductivity of a metal conductive layer, high insulation from electronic component due to heat-resistance and insulation of an insulating layer made of synthetic resin material such as PET and PEN, and excellent heat-resistance against soldering.

In addition, the shield can of the present invention shows high reliability without any insulating tape. In particular, the shield can shows excellent insulation and heat-resistance as a uniform thick insulating layer exists throughout the inner surface thereof covering electronic components, and provides a slimness of electronic components as a unnecessary gap within the shield can for an insulating tape can be omitted. The shield can of the present invention can maintains the above advantages irrespective of different shapes of the shield can.

In addition, the shield can of the present invention has advantages of mass production due to simple manufacturing process with excellent material property and high economics as an attachment process of an insulating tape can be omitted.

### BRIEF DESCRIPTION OF THE DRAWINGS

The above and/or other aspects and advantages of the present invention will become apparent and more readily appreciated from the following description of the embodiments, taken in conjunction with the accompanying drawings of which:

FIG. 1 is a sectional view showing a portion of a shield can plate according to an embodiment of the present invention.

FIG. 2 is a flow chart showing a process of manufacturing the shield can plate according to an embodiment of the present invention.

FIG. 3 is a perspective view of a shield can according to an embodiment of the present invention.

FIG. 4 is a sectional view of the shield can according to an embodiment of the present invention.

### DETAILED DESCRIPTION OF THE PREFERRED EMBODIMENT

Hereinafter, one preferred embodiment of the present invention will be described with reference to the accompanying drawings.

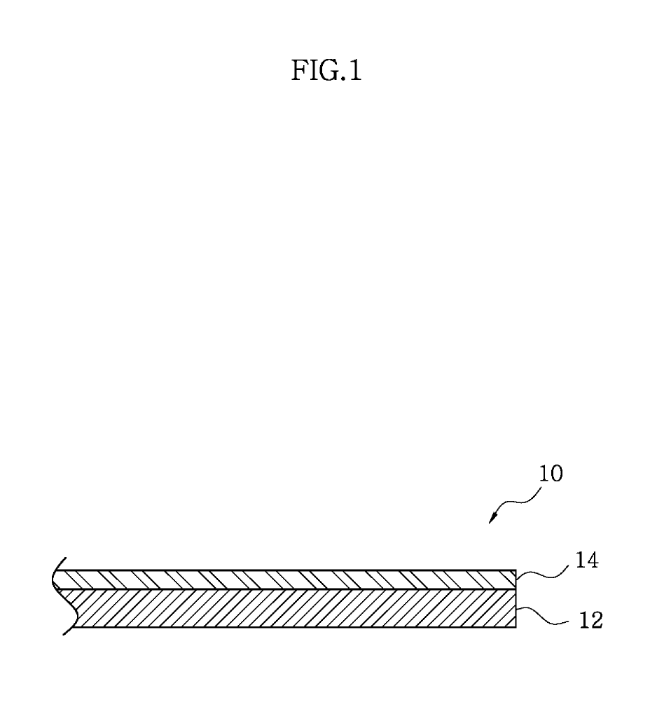

FIG. 1 is a sectional view showing a portion of a shield can plate according to an embodiment of the present invention.

As shown in FIG. 1, a shield can plate 10 according to an embodiment of the present invention has a structure including a conductive layer 12 made of metal and an insulating layer 14 made of synthetic resin and laminated on one side of the conductive layer 12. Specifically, the conductive layer 12 is made of one selected from a group consisting of copper (Cu), zinc (Zn), nickel (Ni), silver (Ag), iron (Fe) and chromium (Cr) or an alloy thereof, or clad metal selected from a group consisting of phosphor bronze/stainless steel/phosphor bronze and german silver/stainless steel/german silver and the insulating layer 14 is made of one of thermoplastic polyester resins including polyethylene terephthalate (PET), polybutylene terephthalate (PBT), polytrimethylene terephthalate (PTT), polycyclohexylene terephthalate (PCT) and polyethylene naphthalate (PEN), or a mixture thereof.

In more detail, the conductive layer 12 is made of one selected from a group consisting of copper (Cu), zinc (Zn), nickel (Ni), silver (Ag), iron (Fe) and chromium (Cr) or an alloy thereof, or clad metal selected from a group consisting of phosphor bronze/stainless steel/phosphor bronze and german silver/stainless steel/german silver and the insulating layer 14 is made of one of thermoplastic polyester resins including polyethylene terephthalate (PET), polybutylene terephthalate (PBT), polytrimethylene terephthalate (PTT), polycyclohexylene terephthalate (PCT) and polyethylene naphthalate (PEN), or a mixture thereof.

Preferably, the conductive layer 12 is made of one of german silver consisting mainly of copper, nickel and zinc, phosphor bronze consisting mainly of copper, tin (Sn) and phosphor (P), brass consisting mainly of copper and zinc, stainless steel consisting mainly of iron and chromium, and beryllium copper consisting mainly of copper and beryllium, or clad metal selected from a group consisting of phosphor bronze/stainless steel/phosphor bronze and german silver/stainless steel/german silver.

However, the conductive layer 12 is not limited thereto but may be made of any materials as long as they have required strength and conductivity. Thickness of the conductive layer 12 is preferably 0.05 to 1 mm although it may be properly varied depending on its purpose.

Preferably, the insulating layer 14 is made of one selected from a group consisting of dicarboxylic acid and aliphatic diol, particularly, one of PET and PEN, which are crystalline polymers. If necessary, the insulating layer 14 made of PET or PEN may be subjected to alignment crystallization. Thickness of the insulating layer 14 is preferably 1 to 70 μm although it may be properly varied depending on its purpose. In addition, the shield can plate 10 uses any available silane-based coupling agent as a primer for coupling between the conductive layer 12 and the insulating layer 14.

The above-configured shield can plate 10 can provide an electromagnetic wave shielding effect due to the conductive layer 12 as well as high insulation and heat-resistance due to the insulating layer 14.

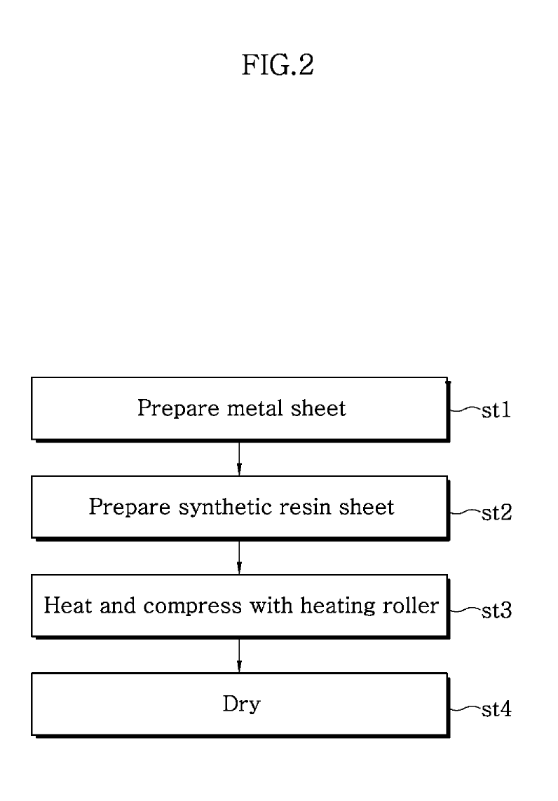

FIG. 2 is a flow chart showing a process of manufacturing the shield can plate 10 according to an embodiment of the present invention.

Referring to FIG. 2 in conjunction with FIG. 1, for the purpose of manufacturing the shield can plate 10, a metal sheet for the conductive layer 12 and a synthetic resin sheet for the insulating layer 14 are first prepared (st1 and st2). At this time, the metal sheet and the synthetic resin sheet may be provided in the form of a roll and their material and thickness are substantially the same as those of the conductive layer 12 and the insulating layer 14.

Subsequently, after heating a pair of heating compressive rollers to 220 to 280° C. and adjusting its pressure to 5 to 30 Kgf/cm², the metal sheet and the synthetic resin sheet are passed between the compressive rollers with these sheets overlapped (st3). At this time, preferably, a silane-based coupling agent may be applied on a bonding surface of the metal sheet or the synthetic resin sheet before it is passed between the compressive rollers. A speed at which the metal sheet and the synthetic resin sheet are passed between the compressive rollers is properly 1 to 10 m/min.

Subsequently, if necessary, a laminate of the metal sheet and the synthetic resin sheet passed through the compressive rollers is dried by a drier to obtain the shield can plate 10 (st4). At this time, the shield can plate may be stored in the form of a roll depending on its purpose. The above-described whole process may be progressed in a reel-to-reel manner.

Hereinafter, the heat-resistance of the shield can plate 10 will be described.

### EXAMPLE 1

A shield can plate was manufactured by drying a laminate of a phosphor bronze-made conductive layer 12 as a 0.15 mm-thick metal sheet and a PET-made insulating layer 14 as a 50 μm-thick synthetic resin sheet after passing it through a pair of compressive rollers of 250° C. and 20 Kgf/cm² at a speed of 2.5 m/min. Then, a first specimen was prepared by cutting the laminate to a size of 183 mm×180 mm. In addition, a second specimen was prepared by cutting PET to the same size for comparison in material property with the first specimen.

Subsequently, the first and second specimens were put in a hot wind circulation drier (JFC-301 available from JONGRO Industrial Co. Ltd.,) and their state change was observed by naked eyes at 250° C. and 260° C. with lapse of 30 seconds, 60 seconds and 90 seconds. Table 2 shows results of the observation.

TABLE 2

| Temperature | Time | State change | |
|---|---|---|---|
| (° C.) | (sec) | First specimen | Second specimen |
| 250 | 30 | Not changed | Edge curled |
| | 60 | Not changed | Edge severely curled |
| | 90 | Not changed | Edge curled and shape |
| | | | deformed |
| 260 | 30 | Not changed | Shape severely deformed |
| | 60 | Not changed | Shape severely deformed |
| | | | and partially melted |
| | 90 | Not changed | Shape severely deformed |
| | | | and melted by more than |
| | | | 3/2 |

It can be seen from the results that the shield can plate 10 has higher heat-resistance at a temperature of more than 250° C. applied when a SMD type shield is soldered. In particular, considering that a high temperature of 250° C. or so is applied for several seconds in a typical soldering, it can be confirmed that the shield can plate 10 of the present invention has excellent heat-resistance since it has no change at 260° C. for 90 seconds. In addition, since the shield can plate 10 of the present invention has no change in conductivity of the conductive layer 12 and insulation of the insulating layer 14 at 260° C. with lapse of 90 seconds, it can be easily expected that it has no deformation in its external appearance even when there is no further result of measurement. Further, considering the fact that PEN has generally higher heat-resistance than that of PET, it can be seen that the shield can plate 10 of the present invention is very suitably utilized for a clip type shield can as well as a SMD type shield can.

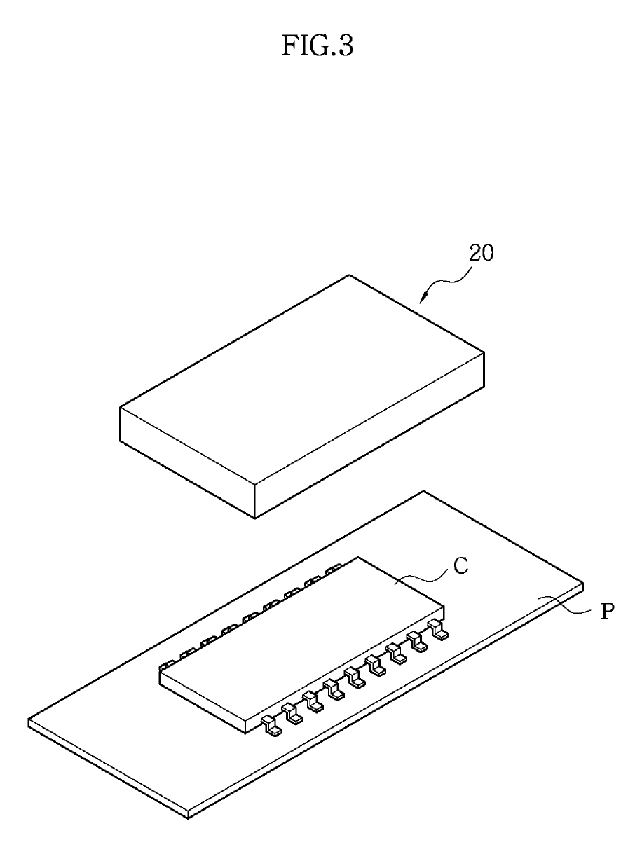

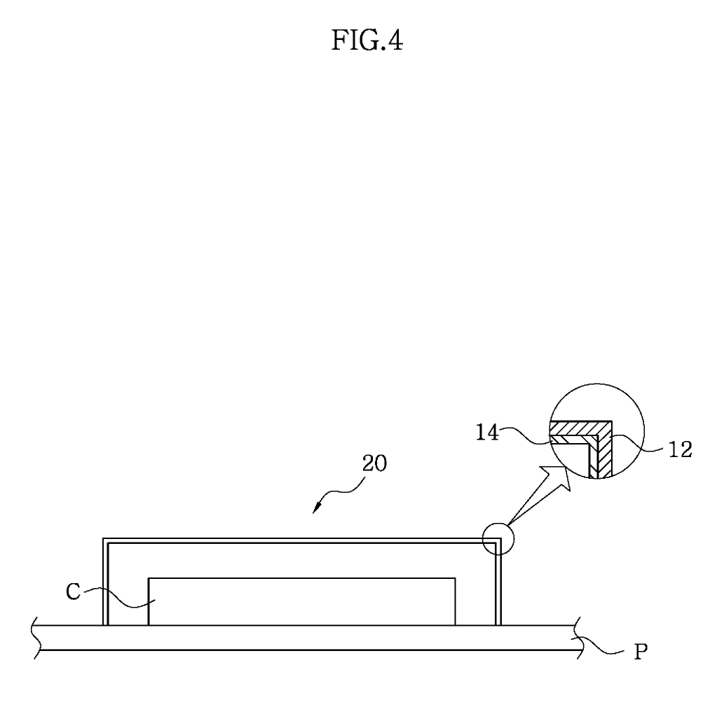

FIG. 3 is a perspective view of a shield can 20 using the shield can plate of present invention, and FIG. 4 is a sectional view of the shield.

As shown in these figures, the shield can 20 of the present invention serves as a cover or similar shape and is soldered to PCB (P) to cover electronic components C mounted on the PCB. A circled portion in FIG. 4 shows a conductive layer 12 exposed to the external and an insulating layer 14 which is laminated along an inner surface of the conductive layer 12 and exhibits an insulating property against the electronic components C.

As apparent from the above, the shield can 20 of the present invention provides electromagnetic wave shielding due to the conductive layer 12 as well as high insulation and heat-resistance due to the insulating layer 14 even when an insulating tape and so on is not used. In addition, although not shown in a separate figure, it is to be understood that the shield can of the present invention may be of a clip type in addition to a SMD type.

Even if a step or a multi-layered structure exists in an inner surface of the shield can of the present invention, the insulating layer 14 can maintain uniform thickness without no deformation.

That is, the insulating layer 14 of the shield can of the present invention does not cause any defects such as excitation and circuit-short due to inherent elongation rate, strength and adhesion of thermoplastic polyester resin such as PET, PEN and so on independent of molding such as press for implementation of shape of the shield can.

While the present invention has been particularly shown and described with reference to exemplary embodiments thereof, it will be understood by those skilled in the art that various changes in form and details may be made therein without departing from the spirit and scope of the present invention. The exemplary embodiments are provided for the purpose of illustrating the invention, not in a limitative sense. Thus, it is intended that the present invention covers the modifications and variations of this invention provided they come within the scope of the appended claims and their equivalents.

1. A shield can plate for a SMD process, comprising:
a metal conductive layer which is made of one selected from a group consisting of copper (Cu), zinc (Zn), nickel (Ni), silver (Ag), iron (Fe) and chromium (Cr) or an alloy thereof, or clad metal, performs an electromagnetic shielding function and maintains a physical structure when a shield can is constructed;
an insulating layer which is made of one or more of polyethylene terephthalate (PET) and polyethylene naphthalate (PEN), which are crystalline polymers, wherein the insulating layer is laminated on one side of the metal conductive layer; and
a silane-based coupling layer interposed between the metal conductive layer and the insulating layer.

2. The shield can plate according to claim 1, wherein the metal conductive layer is made of one selected from a group consisting of german silver, phosphor bronze, brass, stainless and beryllium copper, or clad metal selected from a group consisting of phosphor bronze/stainless steel/phosphor bronze and german silver/stainless steel/german silver, and
wherein the insulating layer is made of one of PET and PEN, which are crystalline polymers, and has a thickness of 1 to 70 μm.

3. A method of manufacturing a shield can plate for a SMD process, comprising:
preparing a metal sheet which is made of one selected from a group consisting of copper (Cu), zinc (Zn), nickel (Ni), silver (Ag), iron (Fe) and chromium (Cr) or an alloy thereof, or clad metal, performs an electromagnetic shielding function and maintains a physical structure when a shield can is constructed;
preparing a synthetic resin sheet in the form of a roll, the synthetic resin sheet being made of one or more of thermoplastic polyester resins including polyethylene terephthalate (PET) and polyethylene naphthalate (PEN), or a mixture thereof; and
drying the metal sheet and the synthetic resin sheet after passing between a pair of compressive rollers with a temperature of 220 to 280° C. and a pressure of 5 to 30 Kgf/cm², at a speed of 1 to 10 mm/min, with the metal sheet and the synthetic resin sheet overlapped,
wherein, before overlapping the metal sheet and the synthetic resin sheet, the method further comprises interposing a silane-based coupling layer, as a primer for adhesion, between the metal sheet and the synthetic resin sheet.

4. A shield can which is formed by a shield can plate for a SMD process according to claim 2 and covers electronic components mounted on a PCB, wherein the shield can is soldered to the PCB and has a cover shape covering the electronic components such that the metal conducive layer is exposed to the external and the insulating layer directs to the electronic components.

5. A shield can which is formed by a shield can plate for a SMD process according to claim 1 and covers electronic components mounted on a PCB, wherein the shield can is soldered to the PCB and has a cover shape covering the electronic components such that the metal conducive layer is exposed to the external and the insulating layer directs to the electronic components.
